(19) United States
(12) Patent Application Publication
(10) Pub. No.: US 2014/0077388 A1
(43) Pub. Date: Mar. 20, 2014

(54) SEMICONDUCTOR DEVICE AND METHOD OF MANUFACTURING THE SAME

(71) Applicant: SAMSUNG ELECTRONICS CO., LTD., Suwon-Si (KR)

(72) Inventors: Hong-Pyo HEO, Yongin-si (KR); Young-soo KWON, Seoul (KR); Jai-kwang SHIN, Anyang-si (KR); Young-tek OH, Yongin-si (KR); Hyung-su JEONG, Suwon-si (KR)

(73) Assignee: SAMSUNG ELECTRONICS CO., LTD., Suwon-Si (KR)

(21) Appl. No.: 13/750,289

(22) Filed: Jan. 25, 2013

(30) Foreign Application Priority Data
Sep. 17, 2012 (KR) 10-2012-0103000

(51) Int. Cl. H01L 23/498; H01L 21/50

(52) U.S. Cl. CPC H01L 23/49827; H01L 21/50
USPC 257/774; 438/107

(57) ABSTRACT

A semiconductor device includes a device chip coupled to an electrode chip. The device chip includes a first device electrode on a first substrate, and the electrode chip includes a first pad electrode extending at least partially through a second substrate. The first pad electrode is electrically connected to the first device electrode and includes spaced conductive sections which serve as a heat dissipating structure to transfer heat received from the device chip and the electrode chip. A method for making a semiconductor device includes using the substrate of the electrode chip as a support during thinning the substrate of the device chip.

### CROSS-REFERENCE TO RELATED APPLICATIONS

This application claims the benefit of Korean Patent Application No. 10-2012-0103000, filed on Sep. 17, 2012, in the Korean Intellectual Property Office, the disclosure of which is incorporated herein in its entirety by reference.

### BACKGROUND

1. Field

The present disclosure relates to semiconductor devices and methods of manufacturing semiconductor devices.

2. Description of the Related Art

A wafer thinning process for manufacturing a semiconductor device is used for a variety of purposes. For example, by removing an unnecessary part of a wafer by a wafer thinning process, an operating resistance of a device, such as an insulated gate bipolar transistor (IGBT), a field effect transistor (FET), a bipolar junction transistor (BJT), and a diode, may be reduced. Such a thinly manufactured chip that is applied to a package may be applied to various fields that require a smaller mounting area.

In general, to have a wafer of over 6 inches thinly processed to have a thickness of about 100 μm or less, a method of using a support wafer or a method of thinning a center portion of a wafer while leaving a wafer edge portion in a ring shape is used. However, the thinning method may cause loss of materials, loss of the wafer edge portion or a wafer handling problem in subsequent processes.

Recently, to improve heat dissipation of a semiconductor package device, various techniques that form a heat dissipation path on both surface sides of a chip are under development. The heat dissipation path is generally formed during a packaging process.

Further, when a bonding wire or a bonding ribbon is bonded to a chip surface to improve bonding reliability and reduce costs, the chip may be damaged due to a bonding force.

### SUMMARY

According to example embodiments, a semiconductor device includes a device chip attached to a lead frame in a packaging process, the device chip including a device substrate and at least one device electrode provided on the device substrate; and an electrode chip attached to the device chip. The electrode chip may include an electrode substrate and at least one pad electrode that penetrates the electrode substrate and is electrically connected to the device electrode.

The pad electrode may include a lower electrode provided on a lower surface of the electrode substrate and bonded to the device electrode, an upper electrode provided on an upper surface of the electrode substrate, and a conductive filler provided in the electrode substrate and electrically connecting the lower electrode and the upper electrode.

A via hole may be penetratingly formed in the electrode substrate and may be filled with the conductive filler to connect the lower electrode and the upper electrode. A plurality of via holes may be penetratingly formed in the electrode substrate and may be filled with the conductive filler to connect the lower electrode and the upper electrode.

A bonding wire, a bonding ribbon, a bonding clip, or a bonding plate may be attached to the upper electrode of the electrode substrate through the packaging process. The device electrode of the device chip and the lower electrode of the electrode chip may be bonded by direct bonding.

An adhesive layer may be further provided between the device electrode of the device chip and the lower electrode of the electrode chip. The adhesive layer may include solder or conductive epoxy.

The electrode substrate may include Si, AlN, glass, or SiC, and the device electrode and the pad electrode each may include Au, Ag, or Cu.

In accordance with other example embodiments, a method of making a semiconductor device comprises providing a device chip including a first device electrode on a first substrate; providing an electrode chip including a first pad electrode extending at least partially through a second substrate; and electrically connecting the first pad electrode to the first device electrode, the first pad including a plurality of spaced conductive sections acting as a heat dissipating structure to transfer heat received from the device chip and the electrode chip.

In accordance with other example embodiments, a method of manufacturing a semiconductor device includes preparing a device wafer including a device substrate and at least one device electrode formed on an upper surface of the device substrate, preparing an electrode wafer including an electrode substrate and at least one pad electrode penetratingly formed in the electrode substrate, providing the electrode wafer on the device wafer and bonding the device electrode and the pad electrode, and thinning the device substrate to a desired thickness by processing a lower surface side of the device substrate.

The method may further include dividing each of the device wafer and the electrode wafer into a plurality of semiconductor devices by a dicing process, after the thinning of the device substrate. The method may further include depositing a metal layer on a lower surface of the device substrate, after the thinning of the device substrate. The method may further include performing a doping process on a lower surface of the device substrate, after the thinning of the device substrate.

### BRIEF DESCRIPTION OF THE DRAWINGS

These and/or other aspects will become apparent and more readily appreciated from the following description of the embodiments, taken in conjunction with the accompanying drawings in which:

FIG. 1 shows an example embodiment of a semiconductor device having example embodiment of an electrode chip.

FIG. 2 shows another example embodiment of an electrode chip that may be included in the semiconductor device of FIG. 1.

FIG. 3 shows another example embodiment of an electrode chip that may be included in the semiconductor device of FIG. 1.

FIG. 4 shows another example embodiment of an electrode chip that may be included in the semiconductor device of FIG. 1.

FIGS. 5 through 8 showing example embodiment of a method for manufacturing a semiconductor device.

### DETAILED DESCRIPTION OF THE EXAMPLE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

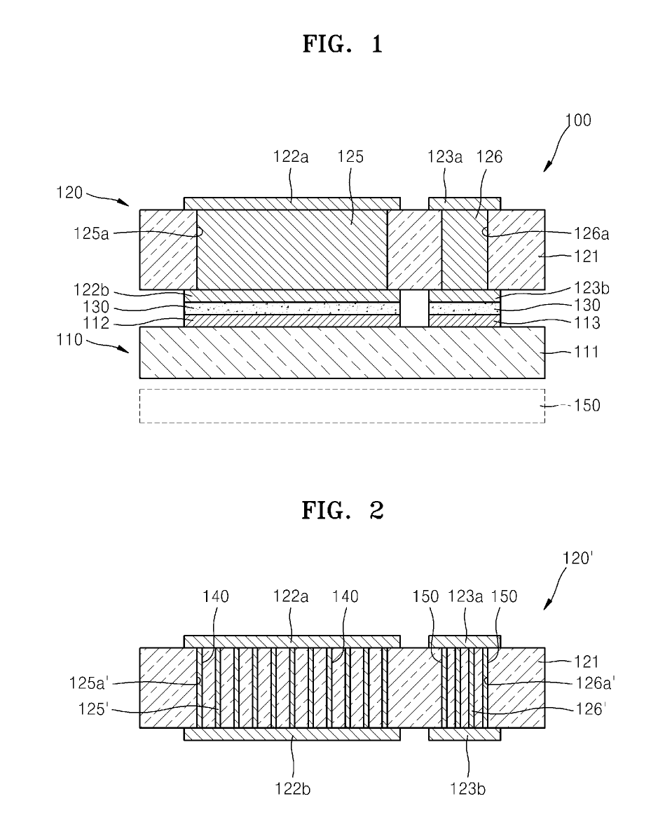

FIG. 1 shows an example embodiment of a semiconductor device 100 which includes a device chip 110 and an electrode chip 120 on the device chip 110. A lower surface of the device chip 110 is attached to a lead frame 150 during a packaging process. The device chip 110 includes a device substrate 111 and first and second device electrodes 112 and 113 that are provided on an upper surface of the device substrate. The device substrate may be, for example, a silicon substrate, a sapphire substrate, a gallium nitride-based substrate, or a glass substrate.

In FIG. 1, one example embodiment is shown to have two device electrodes (namely, first and second device electrodes 112 and 113) on the upper surface of device substrate 111. In other embodiments, a different number of device electrodes (e.g., one or three or more) may be provided on the upper surface of the device substrate 111. Also, a metal layer may be deposited on a lower surface of the device substrate 111, and in a semiconductor device (e.g., an insulated-gate bipolar transistor (IGBT)) the lower surface of the device substrate 111 may be doped.

In addition, the first and second device electrodes 112 and 113 may be made of a material including metal that exhibits superior or at least a predetermined level of conductivity. For example, the first and second device electrodes may contain Au, Ag, or Cu or another metal.

The electrode chip 120 is attached on top of the device chip 110. The electrode chip 120 includes an electrode substrate 121 and first and second pad electrodes. For example, a silicon substrate or an MN substrate having superior or a predetermined level of thermal conductivity may be used as the electrode substrate 121. Alternatively, glass or a SiC substrate may be used as the electrode substrate 121. In other embodiments, the electrode substrate may be made of other materials. The first and second pad electrodes penetrate the electrode substrate 121 and are electrically connected to the first and second device electrodes 112 and 113, respectively.

Although FIG. 1 shows an example embodiment where electrode chip 120 has two pad electrodes, in other embodiments the electrode chip may include one or three or more pad electrodes. Also, the first and second pad electrodes may be made from a metal exhibiting superior or a predetermined level of conductivity. This material may be the same or different from the material used to form first and second electrodes 112 and 113. For example, the first and second pad electrodes may contain Au, Ag, or Cu.

The first pad electrode includes a first lower electrode 122b on a lower surface of the electrode substrate 121, a first upper electrode 122a on an upper surface of the electrode substrate 121, and a first conductive filler 125 provided at least partially within the electrode substrate 121 to electrically connect the first lower electrode 122b and the first upper electrode 122a. The first lower electrode 122b and the first upper electrode 122a may be formed of a same or different material as the first conductive filler 125.

The second pad electrode includes a second lower electrode 123b on the lower surface of the electrode substrate 121 and separate from the first lower electrode 122b, a second upper electrode 123a on the upper surface of the electrode substrate 121 and separate from the first upper electrode 122a, and a second conductive filler 126 provided at least partially within the electrode substrate 121 to electrically connect the second lower electrode 123b and the second upper electrode 123a. The second lower electrode 123b and the second upper electrode 123a may be formed from a same or different material as the second conductive filler 126.

The first lower electrode 122b is bonded to an upper surface of the first device electrode 112. The bonding may be achieved, for example, by an adhesive layer 130 between the first device electrode 112 and the first lower electrode 122b. The adhesive layer 130 may be made from a material which includes, for example, solder or conductive epoxy. The solder may include, for example, Sn—Pb alloy and the conductive epoxy may include, for example, Ag.

More specifically, various bonding techniques may be used for bonding the first lower electrode 122b and the first device electrode 112. For example, in addition to soldering or conductive epoxy bonding techniques, bonding between the first lower electrode 122b and the first device electrode 112 may be achieved by direct bonding.

As shown in FIG. 1, the second lower electrode 123b is bonded to an upper surface of the second device electrode 113. The technique for bonding the second lower electrode 123b and the second device electrode 113 may be the same or different as the technique for bonding the first lower electrode 122b and the first device electrode 112.

The first and second upper electrodes 122a and 123a are surface electrodes of the semiconductor device 100. A bonding wire, a bonding ribbon, a bonding clip, or a bonding plate may be attached on the first and second upper electrodes 122a and 123a in a packaging process. A first via hole 125a, through which the first upper electrode 122a and the first lower electrode 122b are connected, may be formed in the electrode substrate 121. The first via hole 125a is filled with material of the first conductive filler 125. A second via hole 126a, through which the second upper electrode 123a and the second lower electrode 123b are connected, may be formed in the electrode substrate 121. The second via hole 126a is filled with material of the second conductive filler 126.

FIG. 2 shows another example embodiment of electrode chip 120′ that may be included in the semiconductor device of FIG. 1. Unlike the electrode chip of FIG. 1, the conductive fillers in the embodiment of FIG. 2 are configured differently.

More specifically, as shown in FIG. 2, electrode chip 120′ includes electrode substrate 121 and first and second pad electrodes. The first and second pad electrodes penetrate through the electrode substrate 121 and are electrically connected to the first and second device electrodes 112 and 113, respectively.

The first pad electrode includes the first lower electrode 122b, the first upper electrode 122a, and a first conductive filler 125′ that is at least partially within the electrode substrate 121 to electrically connect the first lower electrode 122b and the first upper electrode 122a. The second pad electrode includes the second lower electrode 123b, the second upper electrode 123a, and a second conductive filler 126′ that is at least partially within the electrode substrate 121 to electrically connect the second lower electrode 123b and the second upper electrode 123a.

A plurality of first via holes 125′a, through which the first upper electrode 122a and the first lower electrode 122b are connected, are formed in the electrode substrate 121. The first via holes 125′a are filled to include material corresponding to the first conductive filler 125′. A plurality of second via holes 126′a, through which the second upper electrode 123a and the second lower electrode 123b are connected, are formed in the electrode substrate 121. The second via holes 126′a are filled to include a material corresponding to the second conductive filler 126″.

In this example embodiment, formation of the conductive fillers in the via holes allow the fillers to serve as heat dissipation structures. Because these structures of electrode chip 120′ are coupled to device chip 110, the conductive fillers are able to dissipate heat from the device chip as well as the electrode chip. As a result, heat may be removed from both sides of semiconductor device 100.

Additionally, in the foregoing embodiments, the first and second upper electrodes 122a and 123a on the surface of the electrode chip may be formed to be relatively thick. For example, in the embodiment of FIG. 2, the first and second upper electrodes 122a and 123a may be thicker than the width of one or more of the conductive sections (e.g., vanes) 140 and 150 of the heat dissipation structures formed by the conductive fillers. As a result of this thickness, the semiconductor device may exhibit improved resistance to being damaged, for example, by wire bonding or ribbon bonding during the packaging process, and also clip bonding is possible.

Furthermore, the spacing between conductive sections 140 may be the same or different from the spacing between conductive sections 150. For example, the spacing between conductive sections 140 may be greater than the spacing between conductive sections 150, or vice versa. Also, the spacing between conductive sections 140 are shown to be the same and the same is true of the spacing between conductive sections 150. However, in an alternative example embodiments the spacing between each of sections 140 and 150 may be different.

Also, metal spreading resistance may be reduced by the electrode chip 120 or 120′ in the foregoing embodiments. As a result, operating resistance of the overall semiconductor device 100 may be reduced.

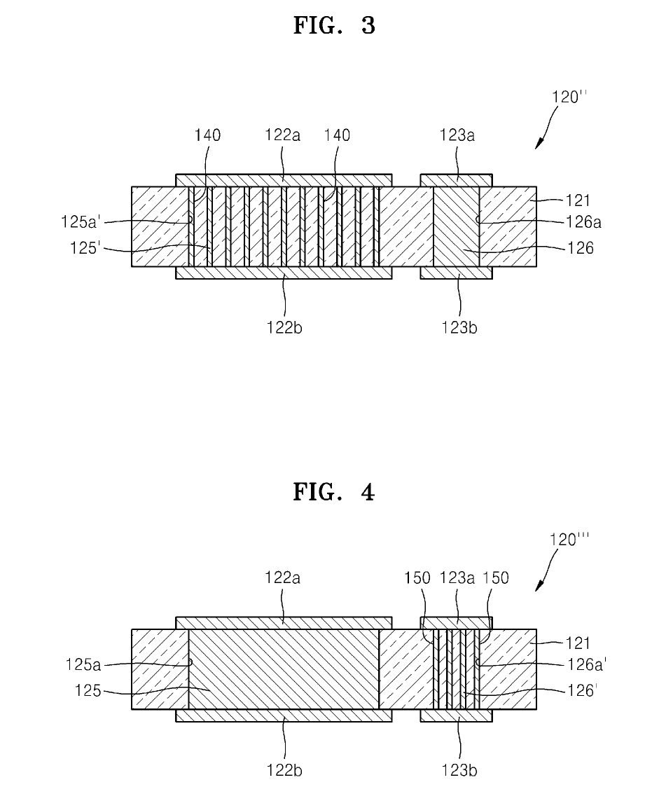

FIG. 3 shows another example embodiment of electrode chip 120″ that may be included in the semiconductor device of FIG. 1. The electrode chip of FIG. 3 includes a conductive filler 125′ with conductive sections 140 and a conductive filler 126 as shown in FIG. 1. Thus, the electrode chip of FIG. 3 has a heat dissipation structure formed at least from the conductive sections of conductive filler 125′ for removing heat from both the electrode chip and device chip of the semiconductor device.

FIG. 4 shows another example embodiment of electrode chip 120′″ that may be included in the semiconductor device of FIG. 1. The electrode chip of FIG. 4 includes a conductive filler 125 as shown in FIG. 1 and a conductive filler 126′ with conductive sections 150. Thus, the electrode chip of FIG. 4 has a heat dissipation structure formed at least from the conductive sections of conductive filler 126′ for removing heat from both the electrode chip and device chip of the semiconductor device.

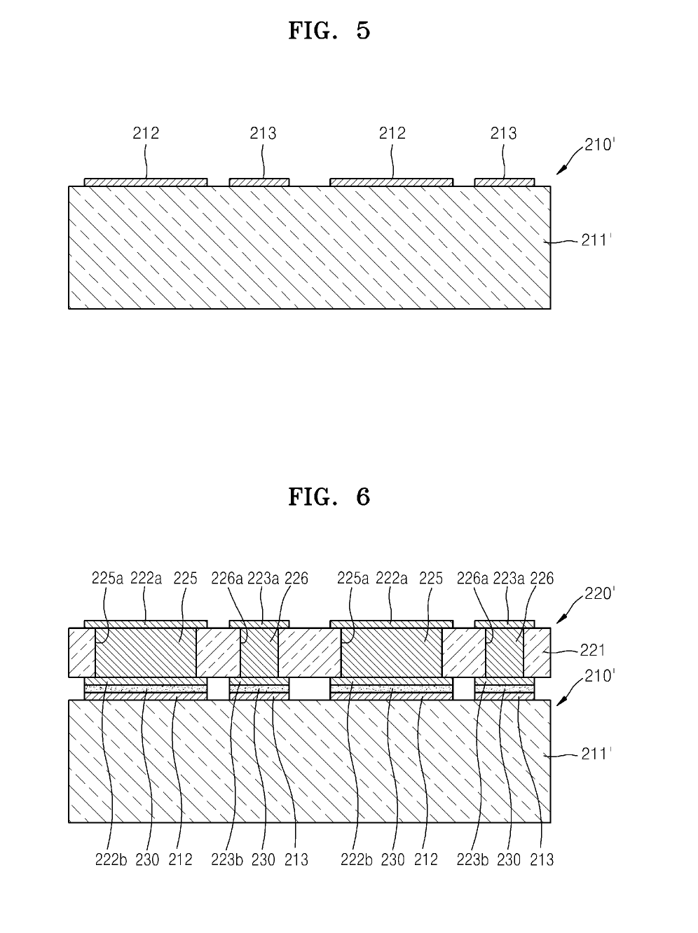

FIGS. 5 through 8 show example embodiment of a method of manufacturing a semiconductor device. An initial operation of the method includes preparing a device wafer 210′. The device wafer may include a device substrate 211′ and first and second device electrodes 212 and 213 formed on an upper surface of the device substrate 211′. The device substrate may be made, for example, of silicon, sapphire, a gallium nitride-based material, glass or another material.

In this embodiment, different pairs of the device electrodes are provided in order to form two devices that will be separated in a subsequent operation. In other embodiments, more than two pairs of device electrodes may be formed and separated to form a corresponding number of semiconductor devices.

In addition to first and second device electrodes 212 and 213, one or more layers of additional materials may be formed on the device substrate 211′ to, for example, conform to a specific application of the device. The first and second device electrodes 212 and 213 may made from a material which includes a metal that exhibits superior or a predetermined level of conductivity. For example, the first and second device electrodes 212 and 213 may contain Au, Ag, or Cu.

Referring to FIG. 6, after the device wafer is prepared, an electrode wafer 220′ may be prepared and bonded to the device wafer 210′. The electrode wafer may include an electrode substrate 221 and first and second pad electrodes provided on the electrode substrate 221. The first and second pad electrodes may be provided in various numbers, for example, corresponding to the number of first and second device electrodes 212 and 213.

A silicon or MN substrate having a superior or predetermined level of thermal conductivity may be used as electrode substrate 221. Alternatively, the electrode substrate may be made of a material including glass or SiC of another material.

The first and second pad electrodes penetrate the electrode substrate 221 and may contain a metal which exhibits a superior or predetermined level of conductivity, for example, like the first and second device electrodes 212 and 213. In example embodiment, the pad electrodes may contain Au, Ag, or Cu.

The first pad electrode includes a first lower electrode 222b provided on a lower surface of the electrode substrate 221, a first upper electrode 222a provided on an upper surface of the electrode substrate 221, and a first conductive filler 225 provided in the electrode substrate 221 to electrically connect the first lower electrode 222b and the first upper electrode 222a. The second pad electrode includes a second lower electrode 223b provided on the lower surface of the electrode substrate 221, a second upper electrode 223a provided on the upper surface of the electrode substrate 221, and a second conductive filler 226 provided in the electrode substrate 221 to electrically connect the second lower electrode 223b and the second upper electrode 223a.

A first via hole 225a through which the first upper electrode 222a and the first lower electrode 222b are connected, and a second via hole 226a through which the second upper electrode 223a and the second lower electrode 223b are connected, may be formed in the electrode substrate 221. The first and second via holes 225a and 226a may be respectively filled with the first second conductive fillers 225 and 226.

The pad electrodes of the electrode wafer 220′ are bonded to the first and second device electrodes 212 and 213 of the device wafer 210′. More specifically, the first and second lower electrodes 222b and 223b are bonded to the first and second device electrodes 212 and 213, respectively. The bonding between the first lower electrode 222b and the first device electrode 212 and the bonding between the second lower electrode 223b and the second device electrode 213 may be performed, for example, by soldering using solder paste or solder bumps. Alternatively, conductive epoxy bonding may be performed using a conductive epoxy paste. The solder material may include, for example, Sn—Pb alloy and the conductive epoxy may include, for example, Ag.

According to the above bonding process, an adhesive layer 230 may be provided between the first lower electrode 222b and the first device electrode 212, and the second lower electrode 223b and the second device electrode 213. The adhesive layer 230 may include solder or conductive epoxy. The bonding between the first lower electrode 222b and the first device electrode 212 and the bonding between the second lower electrode 223b and the second device electrode 213 may also be performed by direct bonding.

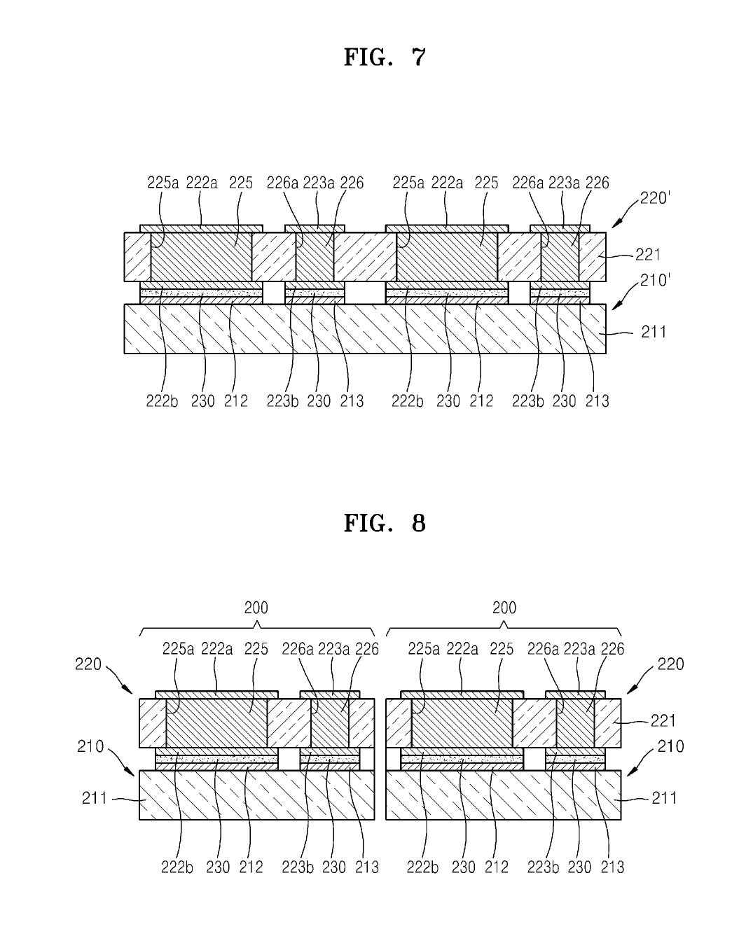

Referring to FIG. 7, in a subsequent operation the device substrate 211′ of the device wafer 210′ is processed to a desired thickness. More specifically, a lower portion of the device substrate 211′ may be processed to reduce a thickness of the device substrate to a desired thickness. Such a thinning process may be performed through grinding and polishing, for example.

In the operation of reducing the thickness of the device substrate, the electrode wafer 220′ attached on the device wafer 210′ may function as a support wafer for supporting the device wafer 210′. According to an example embodiment, the thickness of the device substrate 211′ may be reduced to about 100 μm or less. However, the device substrate 211′ may be reduced to a different thickness in other embodiments depending, for example, on the specific application of the semiconductor device.

After the thickness-reducing operation, a metal layer may be deposited or otherwise formed on a lower surface of a thinned device substrate 211. Also, in order to manufacture a semiconductor device such as an IGBT, a doping process may be performed on a lower surface of the thinned device substrate 211. The doping process may include, for example, performing ion injection into the lower surface of the thinned device substrate 211 and annealing the ion-injected thinned device substrate 211. A metal layer may then be deposited on the lower surface of the device substrate 211.

Referring to FIG. 8, the electrode wafer 220′ and the device wafer 210′ processed to the desired thickness are divided into a plurality of sections through a dicing process. The dicing process produces a plurality of semiconductor devices 200. The dicing process may be performed using a laser, for example.

Each of the semiconductor devices 200 manufactured may include a device chip 210 and an electrode chip 220 bonded to the device chip 210. The device chip 210 includes the thinned device substrate 211 and the first and second device electrodes 212 and 213. The electrode chip 220 includes the electrode substrate 221 and the first and second pad electrodes corresponding to the first and second device electrodes 212 and 213.

In accordance with another embodiment, a semiconductor package is manufactured by performing a packaging process on any of the aforementioned semiconductor devices. In the packaging process, the device chip 210 of each of the semiconductor devices 200 is attached to the lead frame 150 of FIG. 1.

Also, a bonding process may be performed on surface electrodes, that is, the first and second upper electrodes 222a and 223a, of the electrode chip 220. The bonding process may include, for example, wire bonding, ribbon bonding, clip bonding, plate bonding, or another bonding technique.

In accordance with the foregoing method embodiments, the electrode wafer attached to the device wafer may be used as a support wafer for the device wafer in the wafer thinning process and also as the surface electrode after the packaging process without being removed in the subsequent process. As a result, cost of the wafer thinning process may be reduced and the wafer easily handled.

Also, because a chemical adhesive is not used to bond the support wafer to the device wafer in at least example embodiment, a variety of types of subsequent thermal processes may be employed.

Also, because various bonding methods may be applied to the surface electrode of the semiconductor device manufactured through the wafer thinning process, reliability of the packaging process may be obtained.

Also, because a thick electrode layer may be formed on a surface of the semiconductor device in at least example embodiment, the semiconductor device may be prevented from being damaged by wire bonding or ribbon bonding during the packaging process and clip bonding may be employed as well.

Also, because at least example embodiment is formed to have an electrode wafer with one or more heat dissipation structures, heat may be removed from one or both surfaces of the semiconductor device.

Also, because the electrode wafer is attached during the wafer thinning process, package costs may be reduced. Because a thick electrode layer is formed on a surface of the semiconductor device, the semiconductor device may be prevented from being damaged by wire bonding or ribbon bonding during the packaging process and clip bonding may be employed as well.

Also, metal spreading resistance may be reduced and thus an operating resistance of the semiconductor device may be reduced in at least example embodiment.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A semiconductor device comprising:
a device chip including a first device electrode on a first substrate; and
an electrode chip including
a first pad electrode extending at least partially through a second substrate, the first pad electrode electrically connected to the first device electrode, the first pad electrode further including a plurality of spaced conductive sections, the plurality of conductive sections acting as a heat dissipating structure to transfer heat received from the device chip and the electrode chip.

2. The semiconductor device of claim 1, wherein portions of the second substrate of the electrode chip are between respective pairs of the spaced conductive sections of the first pad electrode.

3. The semiconductor device of claim 1, wherein the first pad electrode of the electrode chip comprises:
a first electrode on a first surface of the second substrate;
a second electrode on an second surface of the second substrate; and
a conductive filler that extends at least partially through the second substrate, wherein the conductive filler electrically connects the first and second electrodes and wherein the first electrode is bonded to the first device electrode.

4. The semiconductor device of claim 1, wherein:
the second substrate includes a plurality of holes, and
conductive material is in the holes to form the plurality of spaced conductive sections of the first pad electrode.

5. The semiconductor device of claim 1, wherein the first pad electrode is coupled to at least one of a bonding wire, a bonding ribbon, a bonding clip, or a bonding plate.

6. The semiconductor device of claim 1, further comprising:
an adhesive layer between the first device electrode and the first pad electrode.

7. The semiconductor device of claim 1, further comprising:
a second pad electrode spaced from the first pad electrode, and
a second device electrode spaced from the first device electrode,
wherein the second pad electrode is electrically connected to the first device electrode.

8. The semiconductor device of claim 7, wherein:
the plurality of spaced conductive sections of the first pad electrode extend at least partially through respective holes in the second substrate, and
the second pad electrode extends at least partially through only one hole in the second substrate.

9. The semiconductor device of claim 7, wherein:
the second pad electrode includes a plurality of spaced conductive sections that extend at least partially through respective holes in the second substrate.

10. The semiconductor device of claim 9, wherein the conductive sections of the first pad electrode have a first spacing and the conductive sections of the second pad electrode have a second spacing.

11. The semiconductor device of claim 10, wherein the first spacing is different from the second spacing.

12. A semiconductor device comprising:
a device chip including a first electrode on a first substrate; and
an electrode chip including a second electrode extending through a second substrate and having a heat dissipation structure, the second electrode having a first surface exposed along a first surface of the second substrate and a second surface exposed along a second surface of the second substrate, the second surface of the second electrode electrically connected to the first electrode.

13. The semiconductor device of claim 12, wherein the second electrode includes a plurality of spaced conductive sections corresponding to the heat dissipation structure, and wherein the heat dissipating structure transfers heat received from the device chip and the electrode chip.

14. The semiconductor device of claim 12, wherein the second electrode comprises a first electrode section overlapping the first surface of the second substrate and a second electrode section overlapping the second surface of the second substrate, and a conductive filler material within the second substrate to electrically connect the first and second electrode sections.

15. A method of making a semiconductor device, comprising:
providing a device chip including a first device electrode on a first substrate;
providing an electrode chip including a first pad electrode extending at least partially through a second substrate; and
electrically connecting the first pad electrode to the first device electrode, the first pad electrode including a plurality of spaced conductive sections acting as a heat dissipating structure to transfer heat received from the device chip and the electrode chip.

16. The method of claim 15, wherein portions of the second substrate of the electrode chip are between respective pairs of the spaced conductive sections of the first pad electrode.

17. The method of claim 15, wherein the first pad electrode comprises:
a first electrode on a first surface of the second substrate;
a second electrode on an second surface of the second substrate; and
a conductive filler that extends at least partially through the second substrate, wherein the electrically connecting includes electrically connecting the conductive filler to the first and second electrodes.

18. The method of claim 15, further comprising:
coupling the first pad electrode to at least one of a bonding wire, a bonding ribbon, a bonding clip, or a bonding plate.

19. The method of claim 15, further comprising:
forming an adhesive layer between the first device electrode and the first pad electrode.

20. A method of making a semiconductor device, comprising:
providing a first wafer having a first device electrode on a first substrate;
coupling a second wafer to the first wafer, the second wafer including a first pad electrode at least partially formed through a second substrate;
bonding the first pad electrode to the first device electrode; and
thinning the first substrate to a first thickness using the second wafer as a support for the first wafer.

21. The method of claim 20, wherein the first thickness lies within a range of about 100 μm or less.

22. The method of claim 20, further comprising:
forming the first second wafer by:
forming a hole in the second substrate, and
depositing conductive material in the hole to form the first pad electrode.

23. The method of claim 20, wherein:
the second substrate includes a plurality of first holes, and
conductive material is located in the first holes to form a plurality of spaced conductive sections corresponding to the first pad electrode, wherein the plurality of conductive sections serve as a heat dissipating structure to transfer heat received from the device chip and the electrode chip.

24. The method of claim 23, wherein:
the second substrate includes at least one second hole spaced from the plurality of first holes,
conductive material located in the at least one second hole forms a second pad electrode, wherein the second pad electrode is electrically connected to a second device electrode on the first substrate.

25. The method of claim 23, wherein:
the second substrate includes a plurality of second holes spaced from the plurality of first holes,
conductive material located in the plurality of second holes forms a plurality of spaced conductive sections corresponding to a second pad electrode, wherein the second pad electrode is electrically connected to a second device electrode on the first substrate.

26. The method of claim 25, wherein the conductive sections of the first electrode pad have a different spacing from the conductive sections of the second electrode pad.

27. The method of claim 20, further comprising:
coupling a bonding wire or bonding ribbon to the first pad electrode.

28. The method of claim 20, further comprising:
dividing the first wafer and the second wafer to form a plurality of semiconductor devices.

29. The method of claim 20, further comprising:
depositing a metal layer on a surface of the first substrate, said depositing performed after thinning the first substrate.

30. The method of claim 20, further comprising:
doping a surface of the first substrate, wherein said doping is performed after thinning the first substrate.
